(19) United States
(12) Patent Application Publication
(10) Pub. No.: US 2011/0115063 A1
(43) Pub. Date: May 19, 2011

(54) Integrated Circuit Packaging with Split Paddle

(75) Inventors: Laxminarayan SHARMA, San Diego, CA (US); Raed MOUGHABGHAB, Encinitas, CA (US); Hong YANG, San Diego, CA (US)

(73) Assignee: ENTROPIC COMMUNICATIONS, INC., San Diego, CA (US)

(21) Appl. No.: 12/949,695

(22) Filed: Nov. 18, 2010

Related U.S. Application Data
(60) Provisional application No. 61/262,420, filed on Nov. 18, 2009.

(51) Int. Cl. H01L 23/495

(52) U.S. Cl. 257/676; 257/E23.031

(57) ABSTRACT

An IC package includes ground paddle(s), power paddle(s), a lead frame, a die, and electrically conductive input/output circuit pads, ground circuit pads, and bond wires. The lead frame may include input/output (I/O) pads positioned near the perimeter of the lead frame and around the ground paddle(s) and power paddle(s). The die may be positioned on one of the ground paddles and may include die terminals. Each I/O circuit pad may be positioned on and connected with one of the I/O pads. The ground circuit pads may be positioned on said one ground paddle around the die between the die and the I/O circuit pads. Each ground circuit pad may be connected to said one ground paddle. Each bond wire may connect a die terminal to an I/O circuit pad and/or a ground circuit pad. A bond wire may connect a die terminal to a power paddle.

### CROSS-REFERENCE TO RELATED APPLICATION

This application claims priority under 35 U.S.C. §119(e) from Provisional Application Ser. No. 61/262,420, filed Nov. 18, 2009, the entirety of which is hereby incorporated by reference herein.

### FIELD

This disclosure is directed generally to packages for integrated circuits, and more particularly, some embodiments relate to apparatuses for fixing integrated circuits to packages and packages to printed circuit boards.

### BACKGROUND

In a conventional integrated circuit (IC) package, a die having multiple electrically conductive die terminals is typically mounted on a surface of a lead frame. In one such conventional package, the lead frame typically includes everything in the package but the die and the bond wires, including a central ground paddle. The central ground paddle is sometimes referred to as a ground die attach paddle, because a die may be attached thereon. The ground die attach paddle is surrounded by input/output (“I/O”) circuit pads positioned on the surface of the lead frame near the outer perimeter of the lead frame. The die terminals may be electrically connected to the I/O circuit pads on the surface of the lead frame using electrically conductive bond wires. Some of the die terminals may be electrically connected to I/O circuit pads and/or the ground die attach paddle using downbonds, thereby providing electrical or logical signal routing and connectivity between the die terminals on a top surface of the lead frame, and ground die attach paddles and/or I/O circuit pads on a bottom surface of the lead frame.

As die and package sizes of integrated circuits have been reduced, there have been recent efforts to mount several dies on a single lead frame. In addition, as the functions of integrated circuits have become more complex, the number of die terminals on the lead frame has increased dramatically, leading to a dramatic increase in the number of ground circuit pads and I/O circuit pads required to provide an electrical connection from the bottom surface to the top surface of the lead frame. In addition, the number of bond wires and downbonds has also increased, creating longer wire runs to connect the die terminals to a common ground die attach paddle.

Long bond wires can adversely affect the performance of an IC device. Electrical noise, such as noise caused by parasitic inductance or capacitance, often arises when the bond wires become too long. In the industry, this problem has typically been addressed by selecting expensive packages. Prior solutions involve using a single ground die attach paddle for single or multiple devices and using a common ground die attach paddle used to mount the die and bond source voltage (Vss) bond wires.

### SUMMARY

In some embodiments, an integrated circuit (IC) package includes: (1) one or more ground paddles configured to provide a source voltage, (2) one or more power paddles configured to provide a drain voltage (or multiple drain voltages), (3) a lead frame, (4) an IC die, and (5) electrically conductive input/output (I/O) circuit pads, ground circuit pads, and bond wires. The lead frame may include multiple I/O pads positioned around the ground paddle(s) and around the power paddle(s). The I/O pads may be positioned near the perimeter of the lead frame. The IC die may be positioned on one of the ground paddles and may include multiple electrically conductive die terminals. Each I/O circuit pad may be positioned on and electrically connected with one of the I/O pads. The ground circuit pads may be positioned on said one ground paddle around the die between the die and the I/O circuit pads. Each ground circuit pad may be electrically connected to said one ground paddle. Each bond wire may electrically connect a die terminal to at least one of an I/O circuit pad and a ground circuit pad. At least one of the bond wires may be configured to electrically connect one of the die terminals to one of the power paddles.

In some embodiments, an integrated circuit (IC) includes one or more ground paddles configured to provide a source voltage, one or more power paddles configured to provide a drain voltage, a lead frame, an IC die, a logic circuit, and electrically conductive input/output circuit pads, ground circuit pads, and bond wires. The lead frame may include multiple input/output (I/O) pads positioned around the ground paddle(s) and around the power paddle(s). The I/O pads may be positioned near the perimeter of the lead frame. The IC die may be positioned on one of the ground paddles and may include multiple electrically conductive die terminals. The logic circuit may include logic gates positioned to communicably engage the die terminals. Each I/O circuit pad may be positioned on and electrically connected with one of the I/O pads. The ground circuit pads may be positioned on said one ground paddle around the die between the die and the I/O circuit pads. Each ground circuit pad may be electrically connected to said one ground paddle. Each bond wire may electrically connect a die terminal to at least one of an I/O circuit pad and a ground circuit pad. At least one of the bond wires may be configured to electrically connect one of the die terminals to one of the power paddles.

### BRIEF DESCRIPTION OF THE DRAWINGS

The following will be apparent from elements of the figures, which are provided for illustrative purposes and are not necessarily to scale.

FIG. 1A is a top view of an integrated circuit package, with a ground paddle having two dies attached thereto and a power paddle, in accordance with some embodiments.

FIG. 1B is a top view of an integrated circuit package, with a ground paddle having one die attached thereto and a power paddle, in accordance with some embodiments.

FIG. 2 is a bottom view of an integrated circuit package in accordance with some embodiments.

FIG. 3 is a cross-sectional view of an integrated circuit package taken along section line 3-3 of FIG. 1A.

FIG. 4 is a cross-sectional view of an integrated circuit package taken along section line 4-4 of FIG. 1A.

FIG. 5 is a top view of an integrated circuit package, with a ground paddle and two power paddles, in accordance with some embodiments.

FIG. 6 is a top view of an integrated circuit package, with two ground paddles and two power paddles, in accordance with some embodiments.

FIG. 7 is a top view of an integrated circuit package, with a ground paddle and three power paddles, in accordance with some embodiments.

### DETAILED DESCRIPTION

This description is intended to be read in connection with the accompanying drawings, which are to be considered part of the entire written description.

The embodiments disclosed herein address problems associated with long bond wires for integrated circuit (IC) packaging. In particular, some of the embodiments disclosed herein reduce the need for long bond wires that provide a drain (power supply) voltage (V_{dd}) in Quad Flat No Leads (QFN) packages without compromising the circuit board level performance of such packages. Some embodiments involve splitting the die attach paddle asymmetrically into multiple (e.g., two) distinct shapes. One paddle may be a ground paddle configured to provide a source (ground) voltage (e.g., Vₛₛ), and another paddle may be a power paddle configured to provide power (e.g., V_{dd}).

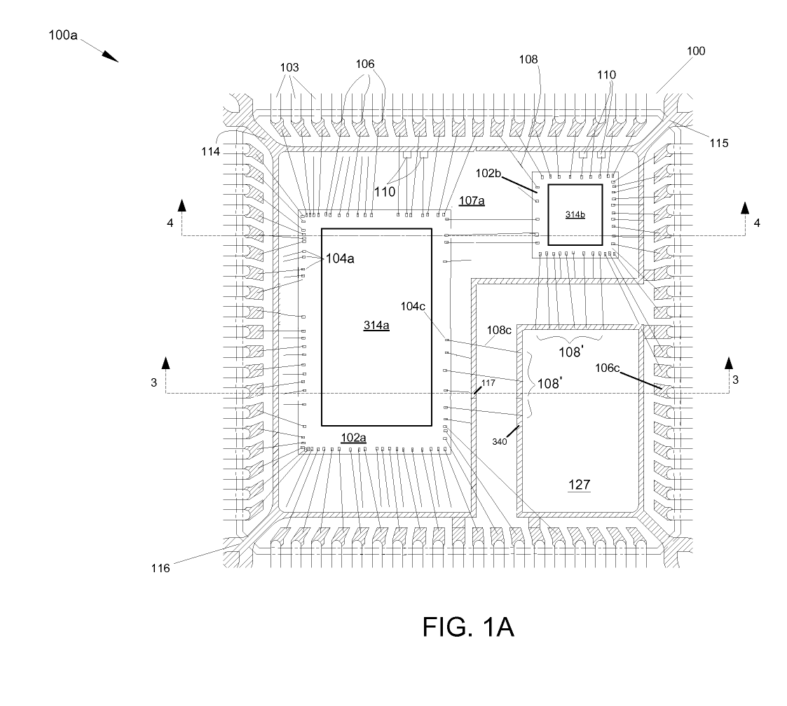

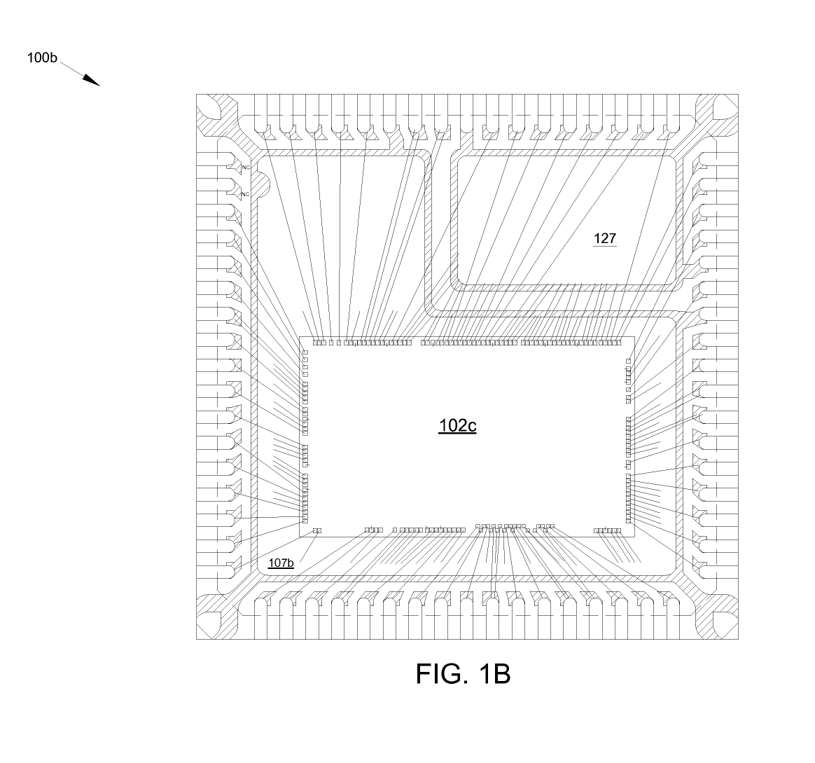

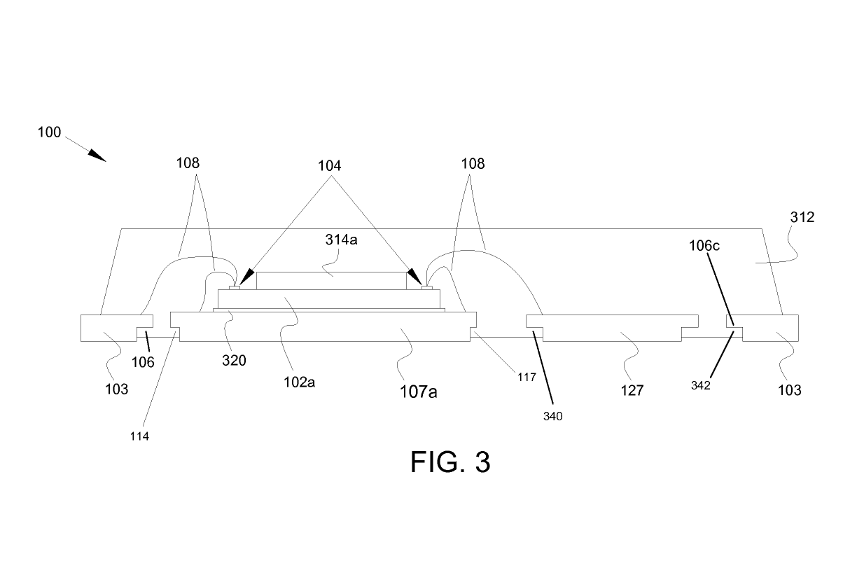

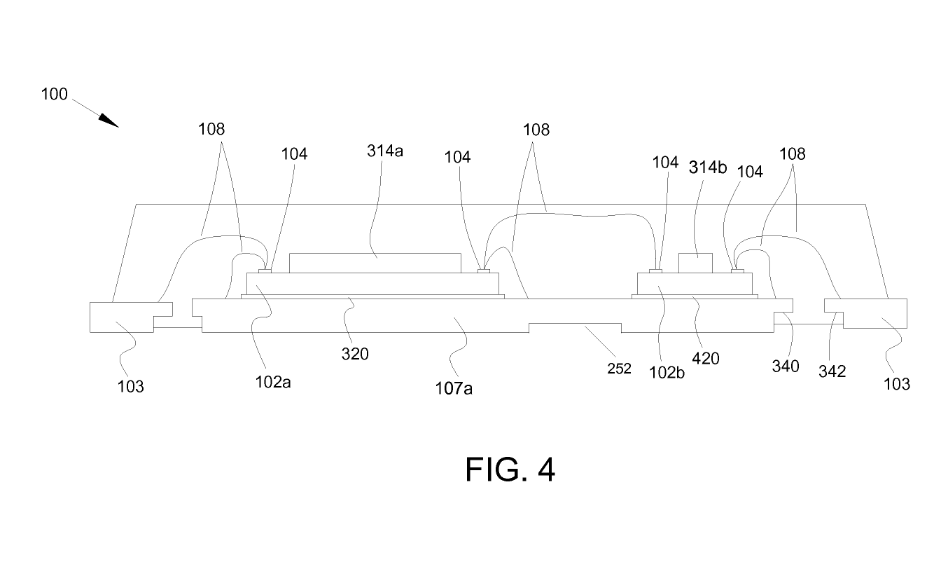

FIG. 1A is a top view of one embodiment of an IC package 100a. The package 100a has a ground die attach paddle (ground paddle 107a) and a power paddle 127. In one embodiment, the ground paddle 107 and power paddle 127 are formed from copper. It will be clear to those skilled in the art that many, many other conductive materials may be used. The ground paddle provides a source (ground) voltage. As shown in FIG. 1A, the ground paddle 107a is essentially L-shaped. The power paddle 127 conforms to two sides of a perimeter of the power paddle. The power paddle is positioned in the corner of the package 100a. Two dies 102a and 102b are attached to the top of the ground paddle 107a. The top left 114, top right 115 and bottom left 116 corners of the ground paddle 107 extend outward to the corner of the package 100a. The outer perimeter 114, 115, 116, 117 of the ground paddle 107a is shown with hashed lines to indicate that it is recessed on the bottom side of the ground paddle 107a, as can be more clearly seen from the cross sections of the package 100a shown in FIGS. 3 and 4 taken along dotted lines 3-3 and 4-4 in FIG. 1A. The recessed area includes the portions 114, 115, 116 of the ground paddle 107a that extend to the corners of the package 100a.

The power paddle 127 provides a drain voltage (power supply voltage). The power paddle 127 is herein referred to as a split power paddle.

The package 100a includes a lead frame 101 that comprises everything in the package 100a but the dies 102a, 102b and the bond wires 108. The lead frame includes multiple input/output (I/O) pads 103 positioned around the perimeter of the lead frame 101. It should be noted that in FIG. 1A, particular I/O pads are denoted as 103. However, it should be understood that all the I/O pads are collectively referenced by reference number 103. The remaining I/O pads 103 are not individually labeled to minimize visual clutter. The same convention applies to other components in the figures throughout this disclosure.

A cross-section of the package 100a through dashed lines 3 and 4 in FIG. 1A allows the I/O pads 103 to be seen more clearly (see FIGS. 3 and 4). An IC die 102a is positioned on the ground paddle 107a. In some embodiments, multiple dies 102a, 102b may be positioned on the ground paddle 107a, as in the example of FIG. 1A in which a die 102b is also positioned on the ground paddle 107a. An example of a single die 102c on the ground paddle 107b is discussed below in the context of FIG. 1B. In the case of multiple dies, the dies are collectively referred to as dies 102. Dies 102a and 102b include respective pluralities of electrically conductive die terminals 104a and 104b (collectively die terminals 104). In addition, in the embodiment shown in FIG. 1A, a multi-pin IC 314a is stacked onto the die 102a. A second multi-pin IC 314b is stacked onto the die 102b.

Package 100a also includes input/output (I/O) circuit pads 106, ground circuit pads 110, and bond wires 108, all of which are electrically conductive. The circuit pads 106 are recessed from the bottom side of the package 100a, as can be seen from FIGS. 3 and 4. Only some of the ground circuit pads 110 are shown in FIG. 1 for visual convenience. The ground circuit pads 110 and the I/O circuit pads 106 may include one or more of the following metals: silver, gold, platinum, palladium, copper, aluminum, tin and nickel. In addition, it will be clear to those skilled in the art that several other conductive materials can be selected. Each I/O circuit pad 106 is positioned on and electrically coupled to one of the I/O pads 103. Ground circuit pads 110 are positioned on the ground paddle 107a around die 102a, between the die 102 and the I/O circuit pads 106. Each ground circuit pad 110 is electrically connected to the ground paddle 107a. The bond wires 108 electrically connect a corresponding die terminal 104 to an I/O circuit pad 106 through the ground paddle 107a. Bond wires 108′ electrically connect respective die terminals 104 to at least one of the I/O circuit pads 106 through the power paddle 127.

By providing a split power paddle 127, bond wires in the package 100a can be made shorter than they otherwise would have to be. For example, bond wires 108′ that are connected to the power paddle 127 in package 100a would, in conventional packaging approaches, have to be much longer in order to reach corresponding I/O circuit pads 106 from which power would conventionally be provided. More particularly, the bond wire 108c attached to the die terminal 104c would have to run all the way across to pad 106c in a conventional packaging approach. However, as shown in FIG. 1A, the bond wire only need go the far shorter distance to the power paddle 127. Thus, the power paddle 127 effectively serves as an extended V_{dd} lead.

FIG. 1B is a top view of an integrated circuit package 100b, with a ground paddle 107b having one die 102a attached thereto. The package 100b of FIG. 1B also includes a power paddle 127. Package 100b is similar to package 100a of FIG. 1A in several respects, but only a single die 102a is used on the L-shaped ground paddle 107b.

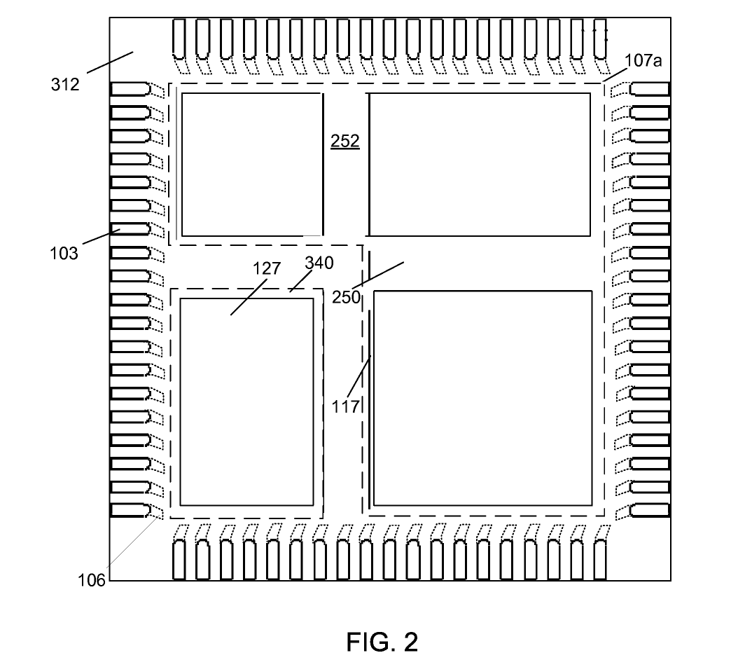

FIG. 2 is a bottom view of an integrated circuit package 100a in accordance with some embodiments. FIG. 2 shows that portion of the ground paddle 107a, the power paddle 127, and I/O pads 103 that are exposed after the molding compound 312 is put over the package 100a. The dashed L-shaped lines of 107a indicate the outline of the ground paddle 107a underneath the molding compound 312. In addition, the pads 106 are buried under the molding compound 312 and are shown in dashed lines in FIG. 2. In some embodiments, areas 250 and 252 of the ground paddle 107a are recesses in the ground paddle 107a. The recesses 250, 252 are etched (e.g., half-etched). Etching is discussed further below in the context of FIG. 3. These recesses 205, 252 are depressions in the surface of the ground paddle 107a, as can be more clearly seen from the cross-sectional view of FIG. 4.

FIG. 3 is a cross-sectional view of the integrated circuit package 100a taken along section line 3-3 of FIG. 1A. I/O pads 103 are shown at both ends (left and right ends) of the package 100a. The die 102a is attached to the ground paddle 107 by a bond adhesive 320 or other suitable adhesive material. Various bond wires 108 electrically connect die terminals 104 to corresponding I/O pads 103, the ground paddle 107, or the power paddle 127. A multi-pin IC 314a is mounted on the die 102a. The multi-pin IC 314a and the die 102a represent one single component connected to the die terminals 104. A mold compound 312 may overlay the lead frame 101, encapsulating and insulating one or more of the die 102a, the bond wires 108, the ground circuit pads 110, and the I/O circuit pads 106. The mold compound may optionally overlay the multi-pin IC 314a as shown in FIG. 3, encapsulating and insulating the IC 314a.

The asymmetry of the split paddle design shown in FIG. 1A may cause board tilt or other distortions when mounting the package 100a to a circuit board (not shown). Such tilting may result in open solder joints between the pads 103 and the board. To address this issue, the bottom of the ground paddle 107a is etched to form recesses 250, 252 to make the package 100a as symmetrical as possible. It should be understood that the term “bottom” as used in this description is relative and is intended only to assist in understanding the relative orientation of the embodiment being described. In FIG. 3, the power paddle 127 is shown as etched at etch region 340, and I/O pad 103 is shown as etched at etch region 342. In some embodiments, the etch regions may exhibit a type of etching known as half-etching, so termed because the portion that is etched away extends halfway up a corresponding component from the bottom side of that component. Providing etched regions (e.g., half-etching) at the bottom side of an IC package in some embodiments enhances the symmetry (achieving an approximately symmetric pattern) and thus allows the package 100a to be more reliably mounted on a board. Additionally, additional mechanical integrity is provided because the mold compound 312 may permeate under a portion of respective etch regions. In other words, the mold compound 312 can grip the etched components better due to such etching.

FIG. 4 is a cross-sectional view of the integrated circuit package 100a taken along section line 4-4 of FIG. 1A. Various components shown in FIG. 4 were described above and do not require further description. FIG. 4 shows a die 102b attached to the ground paddle 107a using bond adhesive 420 (or other suitable adhesive material), in addition to die 102a that was described above in the context of FIG. 3. Referring to FIGS. 1A and 4, the split paddle design in some embodiments utilizes available package space efficiently by situating multiple dies 102a, 102b at respective locations on the shaped ground paddle 107a. FIG. 4 shows the second multi-pin IC 314b mounted on the die 102b in communicable engagement with die terminals 104 of that die 102b.

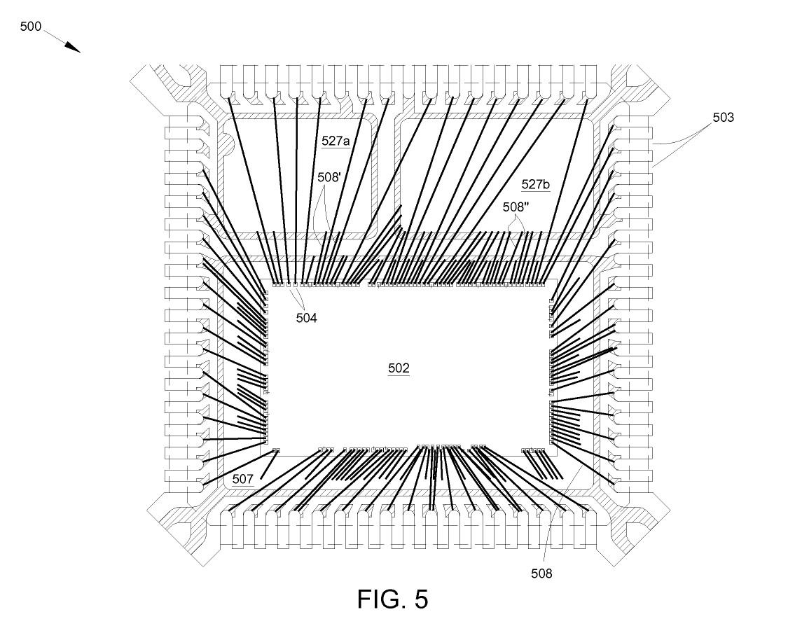

FIG. 5 is a top view of an integrated circuit package 500, with a ground paddle 507 and two power paddles 527a, 527b, in accordance with some embodiments. A die 502 is positioned on the ground paddle 507. Various bond wires 508 are shown. In some embodiments, bond wires 508′ and 508″ only extend from respective die terminals 504 to respective power paddles 527a and 527b, and thus do not need to extend all the way to respective I/O pads 503 as in the prior art. Advantageously, in some embodiments, multiple power paddles 527a and 527b provide different drain voltages.

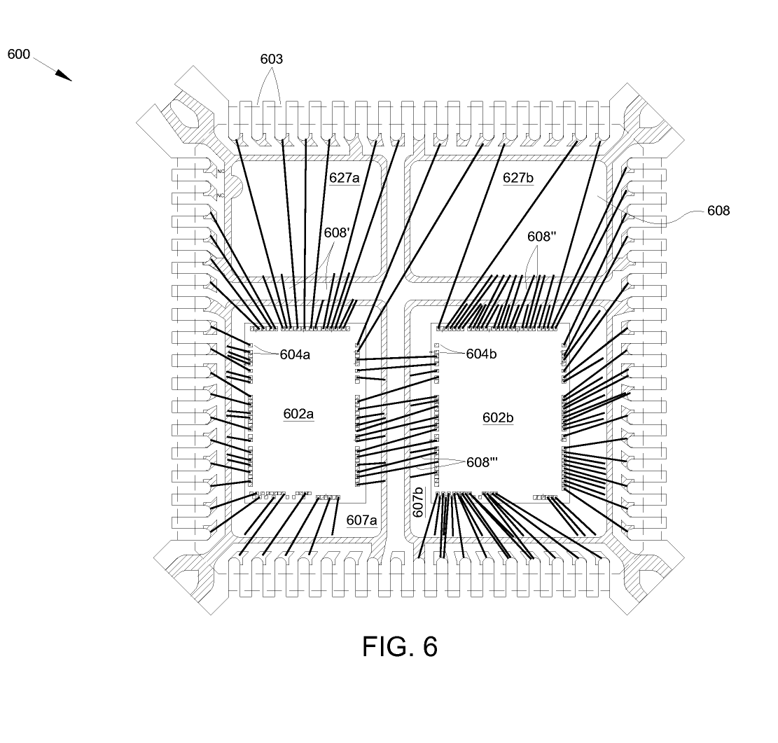

FIG. 6 is a top view of an integrated circuit package 600, with two ground paddles 607a, 607b and two power paddles 627a, 627b, in accordance with some embodiments. In package 600, dies 602a and 602b are disposed on respective ground paddles 607a and 607b. Various bond wires 608 are shown. Bond wires 608′ and 608″ couple respective die terminals 604a, 604b (collectively 604) of corresponding dies to respective power paddles 627a and 627b. Bond wires 608′″ couple die terminals 604a to respective die terminals 604b. In some embodiments, bond wires 608′ and 608″ only extend from respective die terminals 604 to respective power paddles 627a and 627b, and thus do not need to extend all the way to respective I/O pads 603 as in the prior art. Advantageously, in some embodiments, multiple power paddles 627a and 627b provide different drain voltages.

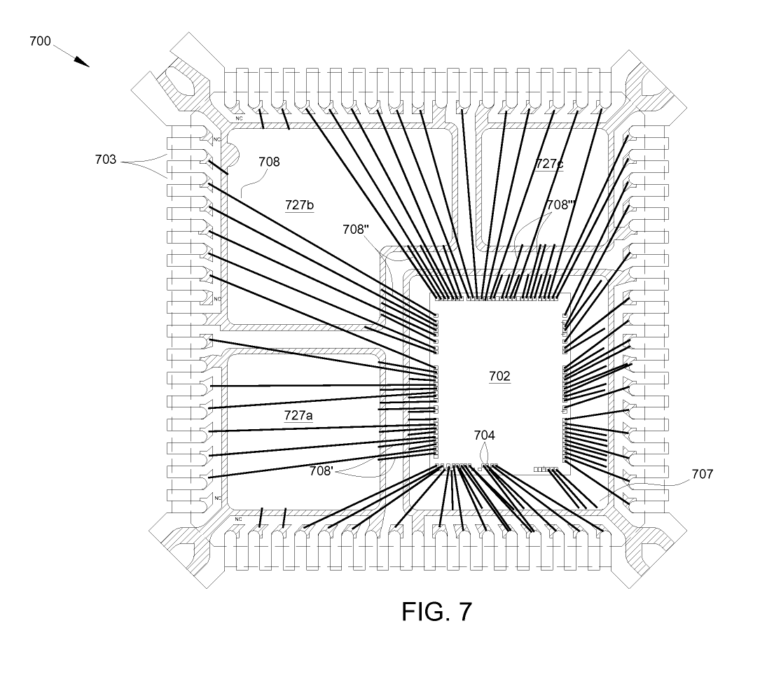

Various other configurations employing a combination of the ground paddle(s) and the power paddle(s) are contemplated as well. In each possible configuration, a power paddle serves as an extended V_{dd} lead and effectively reduces the length of one or more V_{dd} bond wires. For example, FIG. 7 is a top view of an integrated circuit package 700, with a ground paddle 707 and three power paddles 727a, 727b, and 727c, in accordance with some embodiments. In package 700, die 702 is disposed on the ground paddle 707. Various bond wires 708 are shown. In some embodiments, bond wires 708′, 708″, and 708′″ only extend from respective die terminals 704 to respective power paddles 727a, 727b, and 727c, and thus do not need to extend all the way to respective I/O pads 703 as in the prior art. Advantageously, in some embodiments, multiple power paddles 727a, 727b, and 727c provide different drain voltages.

The integrated circuit packages (100a-b, 500, and 600) of each of the embodiments illustrated in FIGS. 1A-7 may also optionally include an integrated circuit (not shown in FIGS. 1A-B, 2, 5, 6, and 7) positioned within the respective integrated circuit die (102a or 102b) and electrically connected to corresponding die terminals 104. The integrated circuit may be virtually any electronic device package, such as a microprocessor, an application specific integrated circuit (ASIC), a programmable logic array (PLA), a non-programmable logic array, a random access memory (RAM), a read only memory (ROM), and the like.

The integrated circuit may include a logic circuit comprising a plurality of logic gates positioned to communicably engage the die terminals. One skilled in the art understands that logic gates include, but are not limited to, one or more AND gates, OR gates, NAND gates, NOR gates, XOR gates, shift registers, storage memory, and the like. In some embodiments, the logic gates are arranged to define a microprocessor including digital processing circuitry and memory. In certain embodiments, the logic circuit resides within an application specific integrated circuit, a programmable logic array, or a read only memory.

The present disclosure allows for short wires that improve the performance of the die and also reduce the cost of the overall package. In addition, the present disclosure provides an effective solder mounting design to improve performance of the board.

While various embodiments of the disclosed method and apparatus have been described above, it should be understood that they have been presented by way of example only and should not limit the claimed invention. Likewise, the diagram depicts an example architectural for the disclosed method and apparatus. This is done to aid in understanding the features and functionality that can be included in the disclosed method and apparatus. The claimed invention is not restricted to the illustrated example architectures or configurations, rather the desired features can be implemented using a variety of alternative architectures and configurations. Indeed, it will be apparent to one of skill in the art how alternative functional, logical or physical partitioning and configurations can be implemented to implement the desired features of the disclosed method and apparatus. Also, different constituent module names other than those depicted herein can be applied to the various partitions. Thus, the breadth and scope of the claimed invention should not be limited by any of the above-described embodiments.

As will become apparent to one of ordinary skill in the art after reading this document, the illustrated embodiments and their various alternatives can be implemented without confinement to the illustrated examples.

What is claimed is:

1. An integrated circuit package comprising:
at least one ground paddle;
at least one power paddle;
an integrated circuit die positioned on one of the ground paddles, the integrated circuit die including a plurality of electrically conductive die terminals;
a plurality of electrically conductive I/O circuit pads; and
a plurality of electrically conductive bond wires, each bond wire electrically connecting a die terminal to at least one of an I/O circuit pads through the at least one power paddle.

2. The integrated circuit package of claim 1, wherein a bottom side of the package is etched to have an approximately symmetric pattern.

3. The integrated circuit package of claim 2, wherein the bottom side of the package is half etched.

4. The integrated circuit package of claim 1, wherein the lead frame includes a power paddle positioned in a corner of the integrated circuit package.

5. The integrated circuit package of claim 4, wherein the integrated circuit package includes exactly one power paddle.

6. The integrated circuit package of claim 4, wherein the integrated circuit package includes a ground paddle having a shape that conforms to two sides of a perimeter of the power paddle that is positioned in the corner.

7. The integrated circuit package of claim 4, wherein the lead frame includes exactly one ground paddle.

8. The integrated circuit package of claim 1, wherein the lead frame includes two power paddles.

9. The integrated circuit package of claim 8, wherein the lead frame includes exactly one ground paddle.

10. The integrated circuit package of claim 8, wherein the lead frame includes two ground paddles.

11. The integrated circuit package of claim 1, further comprising an integrated circuit positioned to engage the die in electrical connection with the plurality of die terminals.

12. The integrated circuit package of claim 11, wherein the integrated circuit is selected from the group consisting of a microprocessor, an application specific integrated circuit (ASIC), a programmable logic array, a non-programmable logic array, a random access memory, and a read only memory.

13. The integrated circuit package of claim 1, wherein the die has a generally rectangular perimeter, and wherein the die terminals are positioned about the die perimeter.

14. The integrated circuit package of claim 1, wherein the lead frame has a plurality of edges defining a generally rectangular area, and wherein the I/O circuit pads are positioned to extend beyond the rectangular area near the edges.

15. The integrated circuit package of claim 1, further comprising at least one bond wire electrically connecting a ground circuit pad to an I/O circuit pad.

16. The integrated circuit package of claim 1, wherein the ground circuit pads and the I/O circuit pads comprise one or more metals selected from the group consisting of silver, gold, platinum, palladium, copper, aluminum, tin and nickel.

17. The integrated circuit package of claim 1, further comprising a bonding material attaching the die to said one ground paddle.

18. An integrated circuit comprising:
one or more ground paddles configured to provide a source voltage;
one or more power paddles configured to provide a drain voltage;
a lead frame including a plurality of input/output (I/O) pads positioned around said one or more ground paddles and around said one or more power paddles, and positioned near the perimeter of the lead frame;
an integrated circuit die positioned on one of the ground paddles, the integrated circuit die including a plurality of electrically conductive die terminals;
a logic circuit comprising a plurality of logic gates positioned to communicably engage the die terminals;
a plurality of electrically conductive I/O circuit pads, each circuit pad positioned on and electrically connected with one of the I/O pads;
a plurality of electrically conductive ground circuit pads positioned on said one ground paddle around the die between the die and the I/O circuit pads, each ground circuit pad electrically connected to said one ground paddle; and
a plurality of electrically conductive bond wires, each bond wire electrically connecting a die terminal to at least one of an I/O circuit pad and a ground circuit pad, at least one of the bond wires electrically connecting one of the die terminals to one of the power paddles.

19. The integrated circuit of claim 18, wherein a bottom side of the package is etched and has an approximately symmetrical pattern.

20. The integrated circuit of claim 18, wherein the lead frame includes a power paddle positioned in a corner of an area defined by the lead frame.

21. The integrated circuit of claim 20, wherein the lead frame includes a ground paddle having a shape that conforms to two sides of a perimeter of the power paddle that is positioned in the corner.

22. The integrated circuit of claim 18, wherein the lead frame includes two power paddles.
